(19) United States
(12) Patent Application Publication
(10) Pub. No.: US 2025/0253261 A1
(43) Pub. Date: Aug. 7, 2025

(54) ELECTRONIC PACKAGE AND MANUFACTURING METHOD THEREOF

(71) Applicant: AaltoSemi Inc., Jiangsu (CN)

(72) Inventors: Yin-Ju CHEN, Jiangsu (CN); Jiun-Hua CHIUE, Jiangsu (CN); Min-Yao CHEN, Jiangsu (CN); De-Long LIU, Jiangsu (CN); Andrew C. CHANG, Jiangsu (CN); Chung-Hsien YANG, Jiangsu (CN); Zhen-Hu CHANG, Jiangsu (CN)

(21) Appl. No.: 19/028,624

(22) Filed: Jan. 17, 2025

(30) Foreign Application Priority Data
Feb. 2, 2024 (CN) 202410156554.4

(51) Int. Cl. H01L 23/538; H01L 21/48; H01L 23/00; H01L 25/00; H01L 25/03

(52) U.S. Cl. CPC H01L 23/5389; H01L 21/4857; H01L 23/5385; H01L 24/24; H01L 25/03; H01L 25/50; H01L 24/16; H01L 2224/16227; H01L 2224/24226

(57) ABSTRACT

An electronic package and a manufacturing method thereof are provided, in which the electronic package includes: a first circuit module including a dielectric material, a first circuit layer, a second circuit layer, a third circuit layer and a fourth circuit layer; a first electronic element embedded in the first circuit module and electrically connected to the fourth circuit layer; a second circuit module electrically connected to the first circuit layer; and a second electronic element located between the first circuit layer and the second circuit module. Accordingly, the overall thickness of the electronic package can be greatly reduced to save space; the heat dissipation effect of the electronic elements can also be improved to extend their service life; and the manufacturing process can also be effectively simplified to improve yield and production rate and reduce manufacturing costs.

### BACKGROUND

### 1. Technical Field

The present disclosure relates to an electronic package and a manufacturing method thereof, and more particularly, to an electronic package that can reduce the overall thickness and a manufacturing method thereof.

### 2. Description of Related Art

Due to the massive popularity and rapid development of smart mobile communication devices and wearable devices, there are increasingly stringent requirements for the semiconductor components used in related products. On the one hand, the number of elements contained therein must be increased to improve processing speed and performance; on the other hand, the area and volume must be reduced to save space. Under this situation, package structures and packaging technologies such as package on a package (POP) architecture are widely used in semiconductor components.

FIG. 1 is a cross-sectional view of a conventional electronic package 1. As shown in FIG. 1, the electronic package 1 includes a first circuit module 11 and a second circuit module 12. The first circuit module 11 may be, for example, a memory module including a memory chip 112 and a memory chip 113. The second circuit module 12 may be, for example, a logic module, and the second circuit module 12 includes an electronic element such as a semiconductor die 121. The first circuit module 11 is bonded to the top of the second circuit module 12 via a plurality of first conductive members 111 made of solder balls. Then, solder balls are disposed on the bottom surface of the second circuit module 12 as second conductive members 122 to form the electronic package 1 such as a ball grid array (BGA) package module.

However, in the conventional electronic package 1, due to the height limitation of the electronic elements on the surface of the second circuit module 12 located below, the overall height of the electronic package 1 cannot be reduced for thinning. As a result, the electronic package 1 needs to occupy a large space in products such as mobile communication devices. Moreover, since the overall thickness cannot be reduced, it is also impossible to increase the total number of elements in the electronic package 1 by stacking more layers of circuit modules and/or elements to improve the overall processing performance. In addition, since at least part of the element located between the first circuit module 11 and the second circuit module 12 usually still needs to be covered with molding materials or underfill UF, etc., when other circuit modules are placed above the element, it will lead to poor heat dissipation, thereby resulting in a loss of performance and lifespan.

Therefore, how to overcome the various problems of the above-mentioned prior art has become an urgent issue to be solved.

### SUMMARY

In view of the various deficiencies of the prior art, the present disclosure provides an electronic package, which comprises: a first circuit module including a dielectric material having a first surface and a second surface opposing the first surface; a first circuit layer, a second circuit layer and a third circuit layer formed in the dielectric material; a fourth circuit layer formed on the second surface; and a first electronic element disposed in the dielectric material and electrically connected to the fourth circuit layer, wherein the first circuit layer is coplanar with the first surface; a second electronic element disposed on the first surface of the dielectric material and electrically connected to the first circuit layer; and a second circuit module disposed above the first surface of the dielectric material and electrically connected to the first circuit layer, wherein the second electronic element is located between the first circuit module and the second circuit module.

In one embodiment, the dielectric material is an Ajinomoto build-up film.

In one embodiment, the dielectric material includes a first insulating layer covering the first circuit layer; a second insulating layer formed on the first insulating layer and covering the second circuit layer; and a third insulating layer formed on the second insulating layer and covering the third circuit layer.

In one embodiment, the first circuit module further includes a plurality of conductive blind vias formed in the dielectric material to electrically connect the first circuit layer and the second circuit layer, to electrically connect the second circuit layer and the third circuit layer, to electrically connect the third circuit layer and the fourth circuit layer, and to electrically connect the first electronic element and the fourth circuit layer.

In one embodiment, the first electronic element is a memory chip.

In one embodiment, the second circuit module includes a thinned substrate with a core layer.

In one embodiment, a thickness of the substrate is less than or equal to 40 μm.

In one embodiment, the electronic package further comprises a solder-resist layer formed on the first surface and the second surface of the dielectric material, so as to expose portions of the first circuit layer and the fourth circuit layer.

In one embodiment, the electronic package further comprises a plurality of first conductive bumps that electrically connect the first circuit layer and the second circuit module.

In one embodiment, the electronic package further comprises a plurality of second conductive bumps that electrically connect the second electronic element and the first circuit layer.

The present disclosure further comprises a method of manufacturing an electronic package, the method comprises: providing a first circuit module including a dielectric material having a first surface and a second surface opposing the first surface; a first circuit layer, a second circuit layer and a third circuit layer formed in the dielectric material; a fourth circuit layer formed on the second surface; and a first electronic element disposed in the dielectric material and electrically connected to the fourth circuit layer, wherein the first circuit layer is coplanar with the first surface; disposing a second electronic element on the first surface of the dielectric material for electrically connecting to the first circuit layer; and disposing a second circuit module above the first surface of the dielectric material for electrically connecting to the first circuit layer, wherein the second electronic element is located between the first circuit module and the second circuit module.

In one embodiment of the method of manufacturing the electronic package, a preparation of the first circuit module includes: forming the first circuit layer on a carrier member; forming a first insulating layer covering the first circuit layer on the carrier member; forming the second circuit layer on the first insulating layer, wherein the second circuit layer is electrically connected to the first circuit layer; forming a second insulating layer on the first insulating layer and the second circuit layer to cover the second circuit layer; forming an opening that exposes portions of the second circuit layer in the second insulating layer for mounting the first electronic element; forming a third insulating layer on the second insulating layer and the third circuit layer and in the opening to cover the third circuit layer and the first electronic element; and forming the fourth circuit layer on the third insulating layer, wherein the fourth circuit layer is electrically connected to the third circuit layer.

In one embodiment of the method of manufacturing the electronic package, the dielectric material is an Ajinomoto build-up film.

In one embodiment of the method of manufacturing the electronic package, the dielectric material includes the first insulating layer covering the first circuit layer; the second insulating layer formed on the first insulating layer and covering the second circuit layer; and the third insulating layer formed on the second insulating layer and covering the third circuit layer.

In one embodiment of the method of manufacturing the electronic package, the preparation of the first circuit module further includes: forming a plurality of first conductive blind vias in the first insulating layer to electrically connect the first circuit layer and the second circuit layer, forming a plurality of second conductive blind vias in the second insulating layer to electrically connect the second circuit layer and the third circuit layer, forming a plurality of third conductive blind vias in the third insulating layer to electrically connect the third circuit layer and the fourth circuit layer and to electrically connect the first electronic element and the fourth circuit layer.

In one embodiment of the method of manufacturing the electronic package, the first electronic element is a memory chip.

In one embodiment of the method of manufacturing the electronic package, the second circuit module includes a thinned substrate with a core layer.

In one embodiment of the method of manufacturing the electronic package, a thickness of the substrate is less than or equal to 40 um.

In one embodiment of the method of manufacturing the electronic package, the method further comprises forming a solder-resist layer on the first surface and the second surface of the dielectric material, so as to expose portions of the first circuit layer and the fourth circuit layer.

In one embodiment of the method of manufacturing the electronic package, the method further comprises forming a plurality of first conductive bumps that electrically connect the first circuit layer and the second circuit module.

In one embodiment of the method of manufacturing the electronic package, the method further comprises forming a plurality of second conductive bumps that electrically connect the second electronic element and the first circuit layer.

As can be seen from the above, in the electronic package and its manufacturing method of the present disclosure, the first electronic element is embedded in the first circuit module, and a thinned substrate is used as the second circuit module, so as to vertically stack multiple circuit modules and the second electronic element, thereby significantly reducing the overall thickness and occupied space of the electronic package using a package on a package (PoP) structure. Moreover, since there is no need to perform a molding process between adjacent circuit module and second electronic element to fill the molding material, the manufacturing process can be effectively simplified. In addition, since the second electronic element is not covered by the molding material and can directly contact the external atmosphere, it has a good heat dissipation effect.

### BRIEF DESCRIPTION OF THE DRAWINGS

FIG. 1 is a schematic cross-sectional view of a conventional electronic package.

FIG. 2A to FIG. 2N are schematic cross-sectional views illustrating a manufacturing method of an electronic package according to an embodiment of the present disclosure.

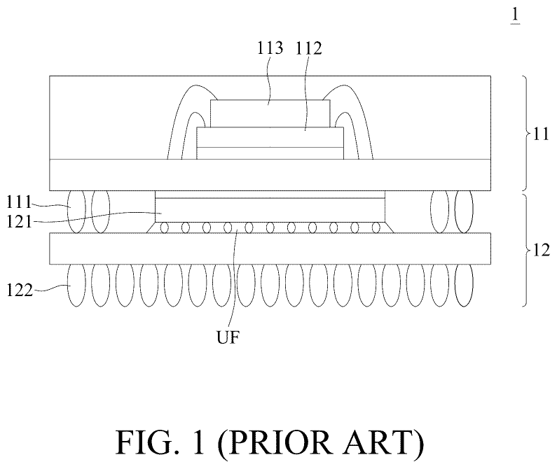

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

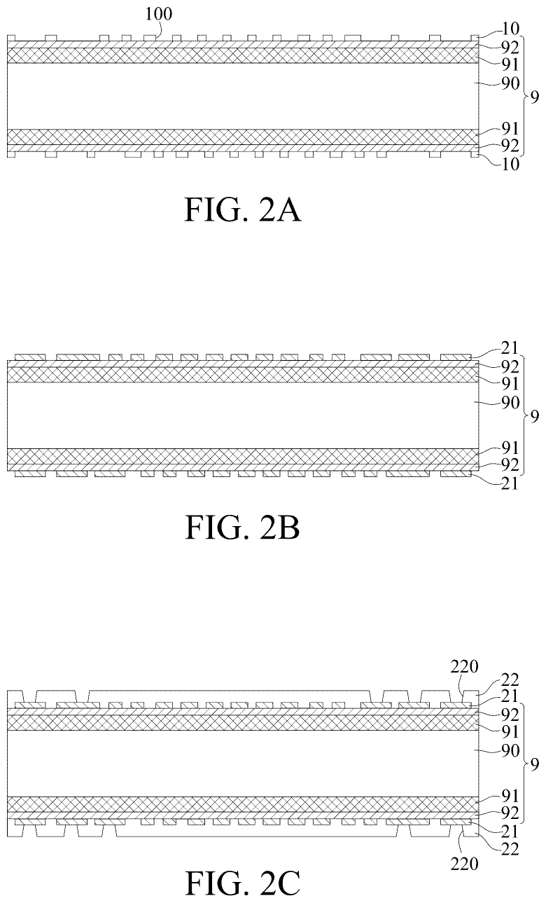

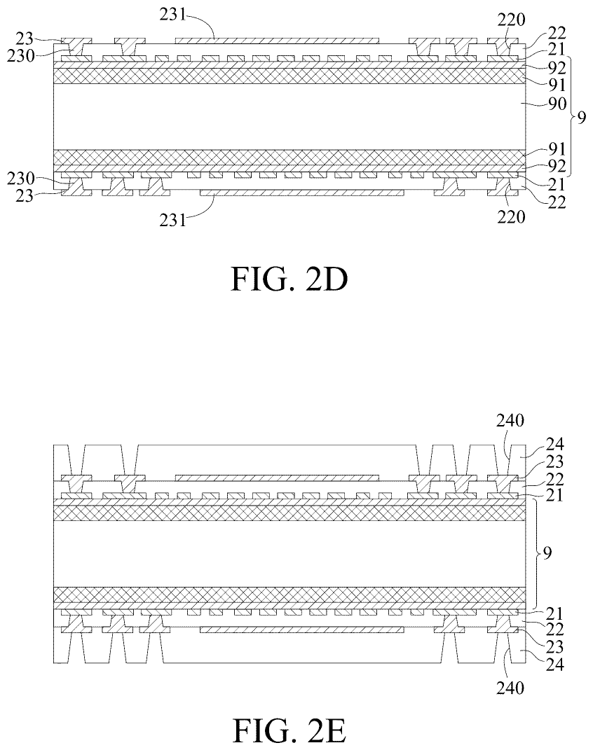

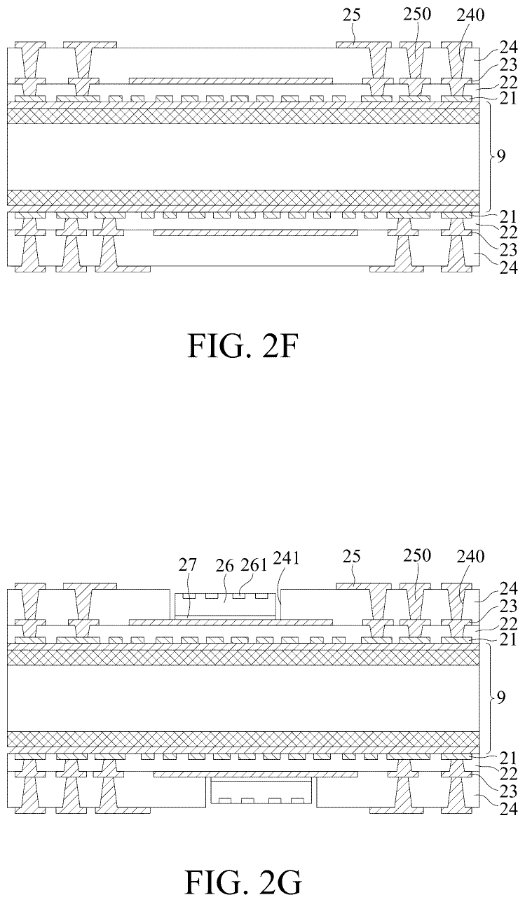

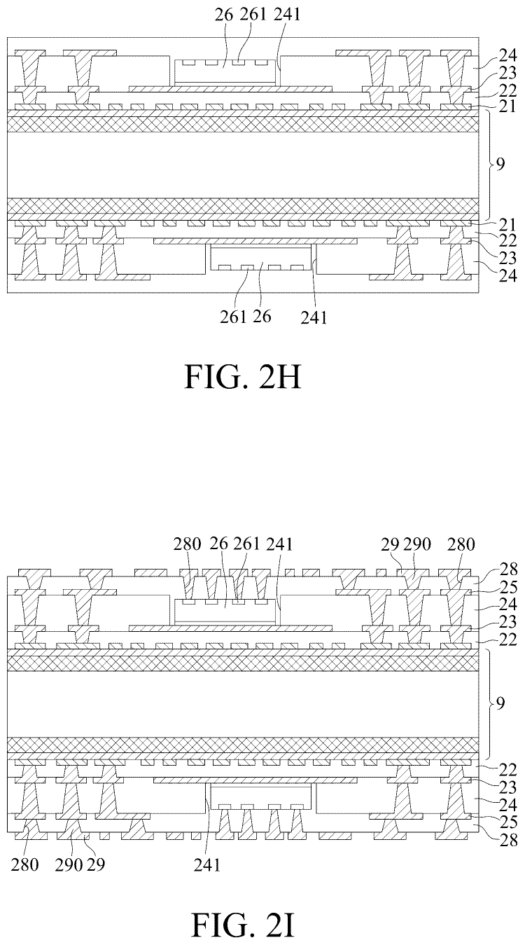

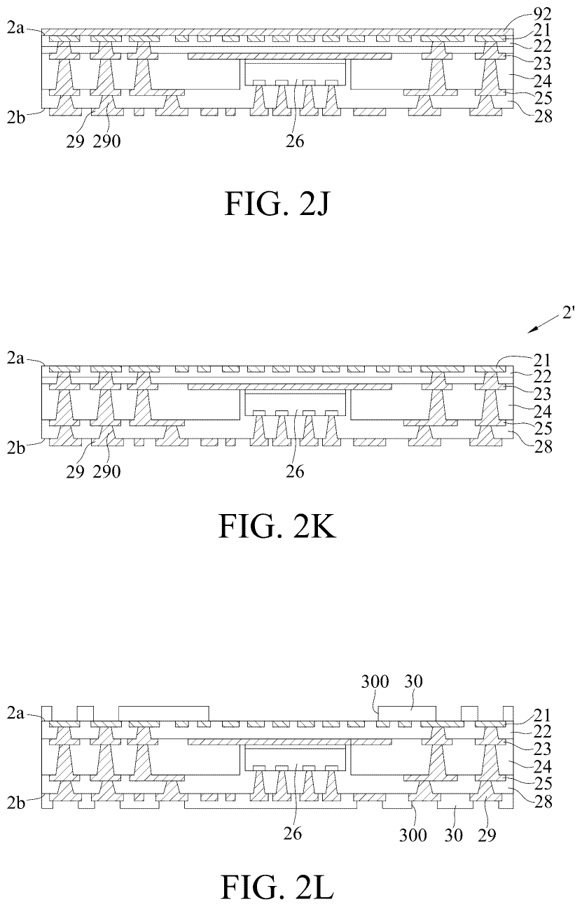

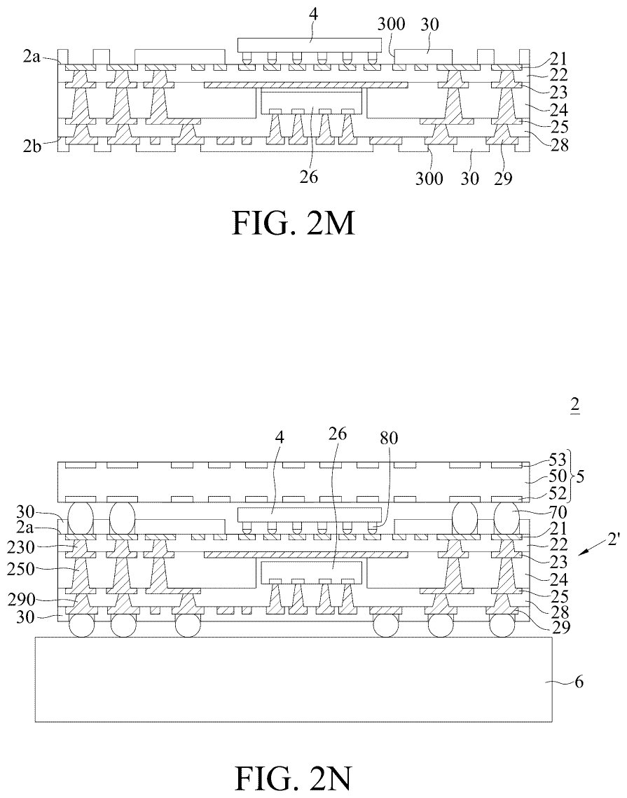

FIG. 2A to FIG. 2N are schematic cross-sectional views illustrating a manufacturing method of an electronic package 2 according to an embodiment of the present disclosure.

As shown in FIG. 2A, a carrier member 9 is provided. The carrier member 9 is a temporary carrier member, which can be a plate with metal layers on opposite sides, such as a copper foil substrate. So called as Detach core in general. The surface of a plate body 90 of the carrier member 9 is provided with a release layer 91, and a metal layer 92 such as a copper layer is formed on the release layer 91. Then, a resist layer 10 having opening areas 100 is symmetrically formed on the opposite sides of the carrier member 9 so that parts of the surface of the carrier member 9 are exposed from the opening areas 100.

As shown in FIG. 2B, a first circuit layer 21 is formed on the metal layer 92 of the opening areas 100. Then, the resist layer 10 is removed.

As shown in FIG. 2C, a first insulating layer 22 covering the first circuit layer 21 is formed on the metal layer 92 of the carrier member 9, then a plurality of blind holes 220 are formed in the first insulating layer 22 by, for example, laser drilling to expose portions of the first circuit layer 21. The material of the first insulating layer 22 may be a dielectric material, such as Ajinomoto build-up film (ABF). Similarly, the selection of the material is also determined according to the requirements of subsequent processes or final products, which is not specific in this embodiment.

As shown in FIG. 2D, copper is electroplated on the first insulating layer 22 and in the blind holes 220, and a patterning process is used to form a second circuit layer 23 on the first insulating layer 22, wherein a plurality of conductive pillars such as conductive blind vias 230 are formed in the blind holes 220 of the first insulating layer 22 to electrically connect the first circuit layer 21 and the second circuit layer 23. In addition, the second circuit layer 23 further includes a chip placement pad 231.

Next, as shown in FIG. 2E, a second insulating layer 24 is formed on the first insulating layer 22 and the second circuit layer 23 by, for example, pressing, to cover the second circuit layer 23. Similarly, a plurality of blind holes 240 can also be formed in the second insulating layer 24 by, for example, laser drilling to expose portions of the second circuit layer 23.

As shown in FIG. 2F, copper is electroplated on the second insulating layer 24 and in the blind holes 240, and a patterning process is used to form a third circuit layer 25 on the second insulating layer 24, wherein a plurality of conductive pillars such as conductive blind vias 250 are formed in the blind holes 240 of the second insulating layer 24 to electrically connect the second circuit layer 23 and the third circuit layer 25.

As shown in FIG. 2G, an opening 241 exposing a portion of the second circuit layer 23 is formed in the second insulating layer 24 by mechanical processing, plasma etching, or laser ablation, and configured for mounting a first electronic element 26, wherein an inactive surface of the first electronic element 26 can be fixed on the chip placement pad 231 via a bonding layer 27 such as an adhesive, and electrical connection pads 261 for power, ground, and/or signal transmission on an active surface of the first electronic element 26 are upwardly exposed from the opening 241.

The first electronic element 26 may be a memory chip, such as a double data rate (DDR) memory chip. Based on the consideration of thinning, the thickness of the first electronic element 26 is less than or equal to 40 μm.

As shown in FIG. 2H, a third insulating layer 28 is formed on the second insulating layer 24 and the third circuit layer 25 and in the opening 241 by, for example, pressing, to cover the third circuit layer 25 and the first electronic element 26. In one embodiment, the material used for the third insulating layer 28 is also the same as the first insulating layer 22 and the second insulating layer 24 mentioned above, and can be an Ajinomoto build-up film.

As shown in FIG. 2I, a plurality of blind holes 280 can be formed in the third insulating layer 28 by, for example, laser drilling to expose portions of the third circuit layer 25 and the electrical connection pads 261 of the first electronic element 26. Then, copper is electroplated on the third insulating layer 28 and in the blind holes 280, and a patterning process is used to form a fourth circuit layer 29 on the third insulating layer 28, wherein a plurality of conductive pillars such as conductive blind vias 290 are formed in the blind holes 280 of the third insulating layer 28 to electrically connect the third circuit layer 25 and the fourth circuit layer 29.

As shown in FIG. 2J, the plate body 90 of the carrier member 9 and the metal layer 92 are separated by the release layer 91, so as to retain the metal layer 92 on the first insulating layer 22 and the first circuit layer 21.

As shown in FIG. 2K, the metal layer 92 is removed by etching to make the surfaces of the first circuit layer 21 and the first insulating layer 22 coplanar.

According to the above, a first circuit module 2′ can be provided, which includes a dielectric material having a first surface 2a and a second surface 2b opposing the first surface 2a; a first circuit layer 21, a second circuit layer 23 and a third circuit layer 25 formed in the dielectric material; a fourth circuit layer 29 formed on the second surface 2b; and a first electronic element 26 disposed in the dielectric material and electrically connected to the fourth circuit layer 29, wherein the first circuit layer 21 is coplanar with the first surface 2a, wherein the dielectric material includes the first insulating layer 22 covering the first circuit layer 21; a second insulating layer 24 formed on the first insulating layer 22 and covering the second circuit layer 23; and a third insulating layer 28 formed on the second insulating layer 24 and covering the third circuit layer 25. Furthermore, the dielectric material may be an Ajinomoto build-up film. In addition, the thickness of the second insulating layer 24 is thicker than that of the first insulating layer 22 and the third insulating layer 28.

As shown in FIG. 2L, a solder-resist layer 30 such as green solder mask is formed on the first surface 2a and the second surface 2b of the dielectric material to protect the first circuit layer 21 and the fourth circuit layer 29. In addition, the solder-resist layer 30 is formed with a plurality of openings 300 to expose portions of the first circuit layer 21 and the fourth circuit layer 29.

As shown in FIG. 2M, a second electronic element 4 electrically connected to the first circuit layer 21 is disposed in the opening 300 (exposing the first circuit layer 21) on the first surface 2a of the dielectric material. In one embodiment, the second electronic element 4 is a packaged semiconductor die. However, the second electronic element 4 can also be other active elements or passive elements that meet the design requirements, and the present embodiment is not limited to as such.

As shown in FIG. 2N, a second circuit module 5 is disposed above the first surface 2a of the dielectric material, and is electrically connected to the first circuit layer 21 and the second circuit module 5, so that the second electronic element 4 is located between the first circuit module 2′ and the second circuit module 5.

Furthermore, in order to meet the requirement of thinning, the second circuit module 5 in this embodiment includes a thinned substrate 50 with a core layer, and a fifth circuit layer 52 and a sixth circuit layer 53 formed on at least one side of the substrate 50 or both sides of the substrate 50 as shown in the figure, wherein the first circuit layer 21 and the fifth circuit layer 52 are electrically connected via a plurality of first conductive bumps 70. In addition, the second electronic element 4 is electrically connected to the first circuit layer 21 via a plurality of second conductive bumps 80.

On the other hand, the electronic package 2 of the present disclosure can also be provided on a printed circuit board 6 via the fourth circuit layer 29 of the first circuit module 2′.

According to the above, the present disclosure provides an electronic package 2, which comprises: a first circuit module 2′ comprising a dielectric material having a first surface 2a and a second surface 2b opposing the first surface 2a; a first circuit layer 21, a second circuit layer 23 and a third circuit layer 25 formed in the dielectric material;

a fourth circuit layer 29 formed on the second surface 2b; and a first electronic element 26 disposed in the dielectric material and electrically connected to the fourth circuit layer 29, wherein the first circuit layer 21 is coplanar with the first surface 2a; a second electronic element 4 disposed on the first surface 2a of the dielectric material and electrically connected to the first circuit layer 21; and a second circuit module 5 disposed above the first surface 2a of the dielectric material and electrically connected to the first circuit layer 21, so that the second electronic element 4 is located between the first circuit module 2′ and the second circuit module 5.

In one embodiment, the dielectric material is an Ajinomoto build-up film.

In one embodiment, the dielectric material includes a first insulating layer 22 covering the first circuit layer 21; a second insulating layer 24 formed on the first insulating layer 22 and covering the second circuit layer 23; and a third insulating layer 28 formed on the second insulating layer 24 and covering the third circuit layer 25.

In one embodiment, the first circuit module 2′ further includes a plurality of conductive blind vias 230 formed in the dielectric material and electrically connected to the first circuit layer 21 and the second circuit layer 23, a plurality of conductive blind vias 250 electrically connected to the second circuit layer 23 and the third circuit layer 25, and a plurality of conductive blind vias 290 electrically connected to the third circuit layer 25 and the fourth circuit layer 29 and electrically connected to the first electronic element 26 and the fourth circuit layer 29.

In one embodiment, the first electronic element 26 is a memory chip.

In one embodiment, the thickness of the first electronic element 26 is less than or equal to 40 μm.

In one embodiment, the second circuit module 5 includes a thinned substrate 50 with a core layer.

In one embodiment, the thickness of the substrate 50 is less than or equal to 40 μm.

In one embodiment, the electronic package 2 further includes a solder-resist layer 30 formed on the first surface 2a and the second surface 2b of the dielectric material, so as to expose portions of the first circuit layer 21 and the fourth circuit layer 29.

In one embodiment, the electronic package 2 further includes a plurality of first conductive bumps 70, which are electrically connected to the first circuit layer 21 and the second circuit module 5.

In one embodiment, the electronic package 2 further includes a plurality of second conductive bumps 80, wherein the second electronic element 4 is electrically connected to the first circuit layer 21 via the plurality of second conductive bumps 80.

To sum up, in the electronic package and its manufacturing method of the present disclosure, the first electronic element, such as a DDR memory chip, is embedded in the first circuit module, and a thinned substrate is used as the second circuit module, so as to vertically stack multiple circuit modules and the second electronic element, thereby significantly reducing the overall thickness and occupied space of the electronic package 2 using a package on a package (PoP) structure. Therefore, more space can be saved under the same architecture, or more elements can be accommodated in the same space and/or more layers of circuit modules can be stacked, thereby resulting in electronic packages that are thinner, lighter, smaller, or have higher processing efficiency. Moreover, since there is no need to perform a molding process between adjacent circuit module and second electronic element to fill the molding material, the manufacturing process can be effectively simplified, the production speed can be accelerated, the manufacturing yield can be improved, and the production cost can be reduced. In addition, since the second electronic element is not covered by the molding material and can directly contact the external atmosphere, it has a good heat dissipation effect, thereby ensuring the reliability and working efficiency of the electronic package and extending the overall life.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a first circuit module including a dielectric material having a first surface and a second surface opposing the first surface; a first circuit layer, a second circuit layer and a third circuit layer formed in the dielectric material; a fourth circuit layer formed on the second surface; and a first electronic element disposed in the dielectric material and electrically connected to the fourth circuit layer, wherein the first circuit layer is coplanar with the first surface;
a second electronic element disposed on the first surface of the dielectric material and electrically connected to the first circuit layer; and
a second circuit module disposed above the first surface of the dielectric material and electrically connected to the first circuit layer, wherein the second electronic element is located between the first circuit module and the second circuit module.

2. The electronic package of claim 1, wherein the dielectric material is an Ajinomoto build-up film.

3. The electronic package of claim 1, wherein the dielectric material includes a first insulating layer covering the first circuit layer; a second insulating layer formed on the first insulating layer and covering the second circuit layer; and a third insulating layer formed on the second insulating layer and covering the third circuit layer.

4. The electronic package of claim 1, wherein the first circuit module further includes a plurality of conductive blind vias formed in the dielectric material to electrically connect the first circuit layer and the second circuit layer, to electrically connect the second circuit layer and the third circuit layer, to electrically connect the third circuit layer and the fourth circuit layer, and to electrically connect the first electronic element and the fourth circuit layer.

5. The electronic package of claim 1, wherein the first electronic element is a memory chip.

6. The electronic package of claim 1, wherein the second circuit module includes a thinned substrate with a core layer.

7. The electronic package of claim 6, wherein a thickness of the substrate is less than or equal to 40 μm.

8. The electronic package of claim 1, wherein the electronic package further comprises a solder-resist layer formed on the first surface and the second surface of the dielectric material, so as to expose portions of the first circuit layer and the fourth circuit layer.

9. The electronic package of claim 1, wherein the electronic package further comprises a plurality of first conductive bumps that electrically connect the first circuit layer and the second circuit module.

10. The electronic package of claim 1, wherein the electronic package further comprises a plurality of second conductive bumps that electrically connect the second electronic element and the first circuit layer.

11. A method of manufacturing an electronic package, comprising:
providing a first circuit module including a dielectric material having a first surface and a second surface opposing the first surface; a first circuit layer, a second circuit layer and a third circuit layer formed in the dielectric material; a fourth circuit layer formed on the second surface; and a first electronic element disposed in the dielectric material and electrically connected to the fourth circuit layer, wherein the first circuit layer is coplanar with the first surface;
disposing a second electronic element on the first surface of the dielectric material for electrically connecting to the first circuit layer; and
disposing a second circuit module above the first surface of the dielectric material for electrically connecting to the first circuit layer, wherein the second electronic element is located between the first circuit module and the second circuit module.

12. The method of claim 11, wherein a preparation of the first circuit module includes:
forming the first circuit layer on a carrier member;
forming a first insulating layer covering the first circuit layer on the carrier member;
forming the second circuit layer on the first insulating layer, wherein the second circuit layer is electrically connected to the first circuit layer;
forming a second insulating layer on the first insulating layer and the second circuit layer to cover the second circuit layer;
forming an opening that exposes portions of the second circuit layer in the second insulating layer for mounting the first electronic element;
forming a third insulating layer on the second insulating layer and the third circuit layer and in the opening to cover the third circuit layer and the first electronic element; and
forming the fourth circuit layer on the third insulating layer, wherein the fourth circuit layer is electrically connected to the third circuit layer.

13. The method of claim 11, wherein the dielectric material is an Ajinomoto build-up film.

14. The method of claim 12, wherein the dielectric material includes the first insulating layer covering the first circuit layer; the second insulating layer formed on the first insulating layer and covering the second circuit layer; and the third insulating layer formed on the second insulating layer and covering the third circuit layer.

15. The method of claim 12, wherein the preparation of the first circuit module further includes: forming a plurality of first conductive blind vias in the first insulating layer to electrically connect the first circuit layer and the second circuit layer, forming a plurality of second conductive blind vias in the second insulating layer to electrically connect the second circuit layer and the third circuit layer, forming a plurality of third conductive blind vias in the third insulating layer to electrically connect the third circuit layer and the fourth circuit layer and to electrically connect the first electronic element and the fourth circuit layer.

16. The method of claim 11, wherein the first electronic element is a memory chip.

17. The method of claim 11, wherein the second circuit module includes a thinned substrate with a core layer.

18. The method of claim 17, wherein a thickness of the substrate is less than or equal to 40 μm.

19. The method of claim 11, wherein the method further comprises forming a solder-resist layer on the first surface and the second surface of the dielectric material, so as to expose portions of the first circuit layer and the fourth circuit layer.

20. The method of claim 11, wherein the method further comprises forming a plurality of first conductive bumps that electrically connect the first circuit layer and the second circuit module; and forming a plurality of second conductive bumps that electrically connect the second electronic element and the first circuit layer.
